(19) United States
(12) Patent Application Publication
(10) Pub. No.: US 2026/0371917 A1
(43) Pub. Date: Nov. 19, 2026

(54) DISPERSION LIQUID, METHOD FOR PRODUCING PHOTOELECTRIC CONVERSION FILM, METHOD FOR PRODUCING PHOTODETECTOR ELEMENT, AND METHOD FOR PRODUCING IMAGE SENSOR

(71) Applicant: FUJIFILM Corporation, Tokyo (JP)

(72) Inventors: Reiko Sugahara, Shizuoka (JP); Takashi Goto, Shizuoka (JP)

(73) Assignee: FUJIFILM Corporation, Tokyo (JP)

(21) Appl. No.: 19/712,699

(22) Filed: Jun. 18, 2026

Related U.S. Application Data
(63) Continuation of application No. PCT/JP2025/006873, filed on Feb. 27, 2025.

(30) Foreign Application Priority Data
Mar. 5, 2024 (JP) 2024-032773

(51) Int. Cl. H10K 85/30; B82Y 15/00; B82Y 20/00; B82Y 40/00; C09D 5/24; C09D 7/40; C09D 7/62; H10K 30/35; H10K 71/12; H10K 71/40

(52) U.S. Cl. CPC H10K 85/361; C09D 5/24; C09D 7/62; C09D 7/67; H10K 30/35; H10K 71/12; H10K 71/40; B82Y 15/00; B82Y 20/00; B82Y 40/00

(57) ABSTRACT

Provided is a dispersion liquid including quantum dots having a band gap of 1.35 eV or less, a ligand, an organic solvent, and water, in which a content of the quantum dots in components obtained by excluding the ligand, the organic solvent, and the water from the dispersion liquid is 50% by mass or more, and a content of the water in the dispersion liquid is 0.001% to 0.3% by mass. Provided is a method for producing a photoelectric conversion film, a photodetector element, and an image sensor, using the dispersion liquid.

### CROSS-REFERENCE TO RELATED APPLICATIONS

This application is a Continuation of PCT International Application No. PCT/JP2025/006873 filed on Feb. 27, 2025, which claims priority under 35 U.S.C § 119(a) to Japanese Patent Application No. 2024-032773 filed on Mar. 5, 2024. Each of the above application(s) is hereby expressly incorporated by reference, in its entirety, into the present application.

### BACKGROUND OF THE INVENTION

### 1. Field of the Invention

The present invention relates to a dispersion liquid including quantum dots. In addition, the present invention relates to a method for producing a photoelectric conversion film, a method for producing a photodetector element, and a method for producing an image sensor.

### 2. Description of the Related Art

In recent years, in the field of smartphones, surveillance cameras, in-vehicle cameras, and the like, photodetector elements capable of detecting light in an infrared range have attracted attention.

In the related art, silicon photodiodes using a silicon wafer as a material of a photoelectric conversion film have been used as photodetector elements used in an image sensor or the like. However, in the silicon photodiodes, the sensitivity is low in an infrared range having a wavelength of 900 nm or more.

In addition, a semiconductor material of an InGaAs system, which is known as a light-receiving element of near-infrared light, has a problem in that a very expensive process is required, such as epitaxial growth or a substrate bonding step, in order to realize a high quantum efficiency, and thus the semiconductor material has not been widely used.

In addition, in recent years, it has been studied to use quantum dots in photoelectric conversion elements. For example, JP2020-150251A discloses that quantum dots having inorganic particles, in which the quantum dots have an organic ligand and an inorganic ligand on the surface thereof, and a molar ratio of the inorganic ligand to the total of the inorganic ligand and the organic ligand is 25% or more and 99.8% or less, are used in a photoelectric conversion film of a photoelectric conversion element.

### SUMMARY OF THE INVENTION

In recent years, with the demand for improving the performance of image sensors and the like, there is also a demand for further improvement in various characteristics required for photodetector elements used in these devices. For example, as the characteristics required for the photodetector element, it is required to have a high external quantum efficiency for light having a target wavelength to be detected by the photodetector element.

As a result of intensive studies on a dispersion liquid containing quantum dots, the present inventors have found that, in a case where the dispersion liquid is stored for a long period of time, aggregates of the quantum dots are likely to be formed in the dispersion liquid. In addition, it has been found that, in a case where such aggregates are contained in a film, the external quantum efficiency is likely to decrease.

Therefore, an object of the present invention is to provide a dispersion liquid which has excellent dispersibility and can form a quantum dot film having a high external quantum efficiency even in a case where a dispersion liquid after long-term storage is used. In addition, another object of the present invention is to provide a method for producing a photoelectric conversion film, a photodetector element, and an image sensor.

The present invention provides the following.
<1> A dispersion liquid comprising:
quantum dots having a band gap of 1.35 eV or less; a ligand; an organic solvent; and water,
in which a content of the quantum dots in components obtained by excluding the ligand, the organic solvent, and the water from the dispersion liquid is 50% by mass or more, and a content of the water in the dispersion liquid is 0.001% to 0.3% by mass.
<2> The dispersion liquid according to <1>, in which the content of the water in the dispersion liquid is 0.01% to 0.1% by mass.
<3> The dispersion liquid according to <1> or <2>, in which the quantum dots are group III-V quantum dots.
<4> The dispersion liquid according to any one of <1> to <3>, in which an average primary particle diameter of the quantum dots is 0.5 nm or more and less than 100 nm.
<5> The dispersion liquid according to any one of <1> to <4>, in which the quantum dots include at least one selected from InAs, InSb, InPAs, or InAsSb.
<6> The dispersion liquid according to any one of <1> to <5>, in which the quantum dots have a maximum absorption in a wavelength range of 900 to 1,700 nm.
<7> The dispersion liquid according to any one of <1> to <6>, in which the ligand includes an inorganic halide.
<8> The dispersion liquid according to any one of <1> to <7>, in which the ligand includes an organic ligand having at least one functional group selected from a carboxy group, a mercapto group, an amino group, a hydroxy group, a phospho group, a phosphonic acid group, or a sulfo group.
<9> The dispersion liquid according to any one of <1> to <8>, in which the organic solvent is a polar solvent.
<10> A method for producing a photoelectric conversion film, comprising: applying the dispersion liquid according to any one of <1> to <9> onto a support to form a composition layer; and drying the composition layer.
<11> A method for producing a photodetector element, comprising the method for producing a photoelectric conversion film according to <10>.
<12> A method for producing an image sensor, comprising the method for producing a photoelectric conversion film according to <10>.

According to the present invention, it is possible to provide a dispersion liquid which has excellent dispersibility and can form a quantum dot film having a high external quantum efficiency even in a case where a dispersion liquid after long-term storage is used. In addition, according to the present invention, it is possible to provide a method for producing a photoelectric conversion film, a photodetector element, and an image sensor.

### BRIEF DESCRIPTION OF THE DRAWINGS

FIG. 1 is a view showing an embodiment of a photodetector element.

### DESCRIPTION OF THE PREFERRED EMBODIMENTS

Hereinafter, the contents of the present invention will be described in detail.

In the present specification, the term “to” is used to mean that numerical values described before and after “to” are included as a lower limit value and an upper limit value, respectively.

In the present specification, in a case where a group (atomic group) is denoted without specifying whether the group is substituted or unsubstituted, the group includes both a group (atomic group) having no substituent and a group (atomic group) having a substituent. For example, the term “alkyl group” includes not only an alkyl group having no substituent (unsubstituted alkyl group) but also an alkyl group having a substituent (substituted alkyl group).

### <Dispersion Liquid>

A dispersion liquid according to the embodiment of the present invention includes
quantum dots having a band gap of 1.35 eV or less, a ligand, an organic solvent, and water,
in which a content of the quantum dots in components obtained by excluding the ligand, the organic solvent, and the water from the dispersion liquid is 50% by mass or more, and a content of the water in the dispersion liquid is 0.001% to 0.3% by mass.

The dispersion liquid according to the embodiment of the present invention has excellent dispersibility, and even in a case where a dispersion liquid after long-term storage is used, a quantum dot film having a high external quantum efficiency can be formed. The reason why such an effect is obtained is presumed to be as follows. It is presumed that, since the dispersion liquid according to the embodiment of the present invention contains 0.001% to 0.3% by mass of water, the water contained in a trace amount is adsorbed on the ligand or the surface of the quantum dot, so that the charge repulsion is increased, the coagulation of the quantum dots in the composition can be suppressed, and excellent dispersibility is obtained. It is presumed that, since the dispersion liquid according to the embodiment of the present invention has excellent dispersibility, a quantum dot film having a high external quantum efficiency can be formed even after long-term storage.

The content of the water in the dispersion liquid can be adjusted to be in the above-described range by adjusting the production conditions of the dispersion liquid or the formulation amount of the water during the production.

The content of the water in the dispersion liquid according to the embodiment of the present invention is preferably 0.01% to 0.1% by mass. According to this aspect, the dispersibility of the quantum dots can be further improved. In addition, a quantum dot film having a higher external quantum efficiency can be formed, and even in a case where a dispersion liquid after long-term storage is used, a quantum dot film having a high external quantum efficiency equivalent to that in a case where a dispersion liquid immediately after production is used can be formed.

The content of the water in the dispersion liquid can be measured by a Karl Fischer method. Specifically, the moisture content in the dispersion liquid can be measured using a Karl Fischer moisture meter (KF-06 manufactured by Mitsubishi Chemical Holdings Corporation), and can be calculated from the following formula.

Content of water in dispersion liquid (moisture content)=(moisture content/dispersion liquid mass)×100

The quantum dot film obtained by using the dispersion liquid according to the embodiment of the present invention can be used for a photodetector element or an image sensor. More specifically, the quantum dot film can be used for a photoelectric conversion film of a photodetector element or an image sensor. Therefore, the dispersion liquid according to the embodiment of the present invention is preferably used as a photoelectric conversion film of a photodetector element or an image sensor. In addition, the quantum dot film obtained by using the dispersion liquid according to the embodiment of the present invention has excellent sensitivity to light having a wavelength in an infrared region. Therefore, an image sensor in which the quantum dot film obtained by using the dispersion liquid according to the embodiment of the present invention is used for a photoelectric conversion film can be particularly preferably used as an infrared sensor. Therefore, the dispersion liquid according to the embodiment of the present invention is preferably used for a photoelectric conversion film of an infrared sensor.

Hereinafter, the dispersion liquid according to the embodiment of the present invention will be described in more detail.

### (Quantum Dot)

The dispersion liquid according to the embodiment of the present invention contains quantum dots. The quantum dot is preferably a semiconductor particle containing a metal atom. In the present specification, the metal atom also includes a metalloid atom represented by a Si atom. In addition, the “semiconductor” in the present specification means a substance having an electrical resistivity of 10⁻² Ωcm or more and 10⁸ Ωcm or less.

The quantum dot preferably contains at least one element selected from the group consisting of Ga, Ge, P, As, Se, In, Sn, Sb, Te, Pb, Bi, Ag, Cu, and Hg, more preferably contains at least one element selected from the group consisting of Ga, P, As, Se, In, Sb, Te, and Bi, and still more preferably contains at least one element selected from the group consisting of P, As, Sb, and In.

The quantum dot is preferably a group III-V quantum dot or a group IV-VI quantum dot, and from the reason that the effect of the present invention is more remarkably exhibited, the group III-V quantum dot is more preferable.

The III-V group quantum dot is a quantum dot containing a Group III element (Group 13 element) and a Group V element (Group 15 element). Examples of the III-V group quantum dot include a quantum dot of a compound semiconductor containing a Group III element and a Group V element. The IV-VI group quantum dot is a quantum dot containing a Group IV element (Group 14 element) and a Group VI element (Group 16 element). Examples of the IV-VI group quantum dot include a quantum dot of a compound semiconductor containing a Group IV element and a Group VI element.

Examples of the Group III element contained in the III-V group quantum dot include a boron (B) element, an aluminum (Al) element, a gallium (Ga) element, and an indium (In) element, and the Group III element preferably contains an In element.

Examples of the Group V element included in the III-V group quantum dots include a nitrogen (N) element, a phosphorus (P) element, an arsenic (As) element, an antimony (Sb) element, and a bismuth (Bi) element, and it is preferable that at least one element selected from the As element or the Sb element be included.

The III-V group quantum dot may further contain an element other than the Group III element and the Group V element. Examples of the other element include a magnesium (Mg) element, a calcium (Ca) element, a strontium (Sr) element, a barium (Ba) element, a zinc (Zn) element, a cadmium (Cd) element, and a mercury (Hg) element.

Examples of the Group IV element contained in the IV-VI group quantum dot include a silicon (Si) element, a germanium (Ge) element, a tin (Sn) element, and a lead (Pb) element, and the Group IV element is preferably a Pb element.

Examples of the Group VI element contained in the IV-VI group quantum dot include an oxygen (O) element, a sulfur (S) element, a selenium (Se) element, and a tellurium (Te) element, and the Group VI element preferably contains at least one element selected from an S element or an Se element, and more preferably contains an S element.

The IV-VI group quantum dot may further contain an element other than the Group IV element and the Group VI element. Examples of the other element include an Mg element, a Ca element, an Sr element, a Ba element, a Zn element, a Cd element, and an Hg element.

Specific examples of the quantum dot include PbS, PbSe, PbSeS, InN, Ge, InAs, InGaAs, CuInS, CuInSe, CuInGaSe, InSb, InPAs, InAsSb, InPSb, HgTe, HgCdTe, Ag₂S, Ag₂Se, Ag₂Te, SnS, SnSe, SnTe, Si, IP, AgBiS₂, and AgBiSTe, and the quantum dot is preferably at least one selected from InAs, InSb, InPAs, InAsSb, InPSb, PbS, or PbSe, and more preferably at least one selected from InAs, InSb, InPAs, or InAsSb.

The band gap of the quantum dot is 1.35 eV or less, preferably 1.1 eV or less, and more preferably 1.0 eV or less. The lower limit value of the band gap of the quantum dot is not particularly limited, and can be 0.5 eV or more. In a case where the band gap of the quantum dot is 1.35 eV or less, a quantum dot film having a higher external quantum efficiency with respect to light having a wavelength in an infrared range can be formed. The band gap of the quantum dot can be calculated from energy at a maximal absorption wavelength of an absorption spectrum obtained by measuring light absorption in a visible to infrared range using an ultraviolet-visible-near infrared spectrophotometer. In addition, in a case of a quantum dot having no maximal absorption wavelength, the band gap can be obtained from a Tauc plot as described in JP5949567B.

The quantum dot preferably has a maximum absorption in a wavelength range of 900 to 1,700 nm, and more preferably has a maximum absorption in a wavelength range of 1,300 to 1,600 nm. By using such a quantum dot, a quantum dot film having a higher external quantum efficiency with respect to light having a wavelength in an infrared range can be formed.

It is also preferable that the quantum dot has high absorption with respect to light having any wavelength in a wavelength range of 900 to 1,700 nm (preferably, a wavelength range of 1,300 to 1,600 nm). By using such a quantum dot, a quantum dot film having a higher external quantum efficiency with respect to light having a wavelength in an infrared range can be formed.

An average primary particle diameter of the quantum dots is preferably 0.5 nm or more and less than 100 nm. A lower limit value of the average primary particle diameter of the quantum dots is preferably 1 nm or more, more preferably 2 nm or more, and still more preferably 3 nm or more. An upper limit value of the average primary particle diameter of the quantum dots is preferably 30 nm or less, more preferably 20 nm or less, and still more preferably 15 nm or less. In a case where the average primary particle diameter of the quantum dots is in the above-described range, a quantum dot film having a higher external quantum efficiency with respect to light having a wavelength in an infrared range can be formed. In the present specification, a value of the average primary particle diameter of the quantum dots is an average value of primary particle diameters of 10 quantum dots randomly selected. For measuring the primary particle diameter of the quantum dots, a transmission electron microscope may be used.

A content of the quantum dots in the dispersion liquid is preferably 1% to 25% by mass. A lower limit thereof is preferably 2% by mass or more, and more preferably 3% by mass or more. An upper limit thereof is preferably 20% by mass or less.

In addition, the content of the quantum dots in the dispersion liquid is preferably 10 to 250 mg/mL. A lower limit thereof is preferably 20 mg/mL or more, and more preferably 30 mg/mL or more. An upper limit thereof is preferably 200 mg/mL or less.

A content of the quantum dots in the components of the dispersion liquid from which the ligand, the organic solvent, and the water are removed is 50% by mass or more, preferably 60% by mass or more, more preferably 70% by mass or more, still more preferably 80% by mass or more, even still more preferably 90% by mass or more, and particularly preferably 95% by mass or more.

In addition, a total content of the quantum dots and the ligand in the components of the dispersion liquid from which the organic solvent and the water are removed is preferably 60% by mass or more, more preferably 70% by mass or more, still more preferably 80% by mass or more, even still more preferably 90% by mass or more, and particularly preferably 95% by mass or more. An upper limit thereof can be set to 100% by mass or less.

### (Ligand)

The dispersion liquid according to the embodiment of the present invention contains a ligand. Examples of the ligand include an inorganic ligand and an organic ligand. The ligand preferably includes an inorganic ligand. The inorganic ligand is preferably an inorganic halide. In the dispersion liquid according to the embodiment of the present invention, in a case where an inorganic halide is used as the ligand, the effect of the present invention is more remarkably exhibited. The reason why such an effect is obtained is presumed to be as follows. That is, it is presumed that, since the dispersion liquid according to the embodiment of the present invention contains a predetermined amount of water, a part of the inorganic halide is substituted with a hydroxy group by the water contained in the dispersion liquid, and thus capping of the quantum dots is promoted, and as a result, the occurrence of surface defects of the quantum dots can be suppressed.

Examples of the halogen atom contained in the inorganic halide include a fluorine atom, a chlorine atom, a bromine atom, and an iodine atom, and a bromine atom or an iodine atom is preferable. In addition, the inorganic halide is preferably a compound containing at least one atom selected from the group consisting of Zn, Cd, Ga, Ge, As, Se, In, Sn, Sb, Te, Tl, Pb, Bi, and Po.

Specific examples of the inorganic ligand include zinc iodide, zinc bromide, zinc chloride, indium iodide, indium bromide, indium chloride, cadmium iodide, lead chloride, lead bromide, lead iodide, cadmium bromide, cadmium chloride, gallium iodide, gallium bromide, gallium chloride, potassium sulfide, and sodium sulfide.

The organic ligand is preferably a compound having at least one functional group selected from a carboxy group, a mercapto group, an amino group, a hydroxy group, a phospho group, a phosphonic acid group, or a sulfo group, more preferably a compound having at least one functional group selected from a carboxy group, a mercapto group, an amino group, or a hydroxy group, and still more preferably a compound having a mercapto group. The organic ligand may be a monodentate ligand having only one of the above-described functional groups, or may be a multidentate ligand having two or more of the above-described functional groups.

The organic ligand is also preferably a compound having a pKa of 3 or less. From the viewpoint that a quantum dot film having a high external quantum efficiency and a more suppressed dark current can be formed, the pKa of the above-described compound is more preferably 2.5 or less. The lower limit of the pKa of the above-described compound is preferably −2.0 or more, more preferably −1.0 or more, and still more preferably 0.5 or more.

Specific examples of the monodentate ligand include 2-naphthylamine, 4-methylthioaniline, 4-methylbenzenethiol, 3,5-dimethylbenzenethiol, 4-chlorobenzenethiol, 4-methoxybenzenethiol, benzoic acid, phenylphosphonic acid, methanesulfonic acid, trifluoroacetic acid, bromoacetic acid, 3-phosphorylpropionic acid, glycine-N,N-bis(methylenephosphonic acid), 2-chloroethylphosphonic acid, phenyl phosphate, dimethyl phosphate, and trifluoromethanesulfonic acid. Among the above-described compounds, phenylphosphonic acid, methanesulfonic acid, trifluoroacetic acid, bromoacetic acid, 3-phosphorylpropionic acid, glycine-N,N-bis(methylenephosphonic acid), 2-chloroethylphosphonic acid, phenyl phosphate, dimethyl phosphate, and trifluoromethanesulfonic acid are compounds having a pKa of 3 or less.

Examples of the multidentate ligand include ligands represented by any of Formulae (A) to (C).

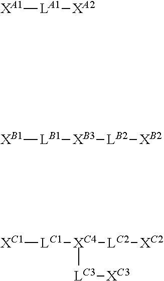

In Formula (A), X^{A1} and X^{A2} each independently represent a carboxy group, a mercapto group, an amino group, a hydroxy group, a phospho group, a phosphonic acid group, or a sulfo group, and
L^{A1} represents a hydrocarbon group.

In Formula (B), X^{B1} and X^{B2} each independently represent a carboxy group, a mercapto group, an amino group, a hydroxy group, a phospho group, a phosphonic acid group, or a sulfo group,
X^{B3} represents S, O, or NH, and
L^{B1} and L^{B2} each independently represent a hydrocarbon group.

In Formula (C), X^{C1} to X^{C3} each independently represent a carboxy group, a mercapto group, an amino group, a hydroxy group, a phospho group, a phosphonic acid group, or a sulfo group,
X^{C4} represents N, and
L^{C1} to L^{C3} each independently represent a hydrocarbon group.

The amino group represented by X^{A1}, X^{A2}, X^{B1}, X^{B2}, X^{C1}, X^{C2}, and X^{C3} is not limited to —NH₂, and also includes a substituted amino group and a cyclic amino group. Examples of the substituted amino group include a monoalkylamino group, a dialkylamino group, a monoarylamino group, a diarylamino group, and an alkylarylamino group. As the amino group represented by these groups, —NH₂, a monoalkylamino group, and a dialkylamino group are preferable, and —NH₂ is more preferable.

The hydrocarbon group represented by L^{A1}, L^{B1}, L^{B2}, L^{C1}, L^{C2}, and L^{C3} is preferably an aliphatic hydrocarbon group or a group having an aromatic ring, and more preferably an aliphatic hydrocarbon group. The aliphatic hydrocarbon group may be a saturated aliphatic hydrocarbon group or an unsaturated aliphatic hydrocarbon group. The number of carbon atoms in the hydrocarbon group is preferably 1 to 20. The upper limit of the number of carbon atoms is preferably 10 or less, more preferably 6 or less, and still more preferably 3 or less. Specific examples of the hydrocarbon group include an alkylene group, an alkenylene group, an alkynylene group, and an arylene group.

Examples of the alkylene group include a linear alkylene group, a branched alkylene group, and a cyclic alkylene group, and a linear alkylene group or a branched alkylene group is preferable and a linear alkylene group is more preferable. Examples of the alkenylene group include a linear alkenylene group, a branched alkenylene group, and a cyclic alkenylene group, and a linear alkenylene group or a branched alkenylene group is preferable and a linear alkenylene group is more preferable. Examples of the alkynylene group include a linear alkynylene group and a branched alkynylene group, and a linear alkynylene group is preferable. The arylene group may be a monocyclic ring or a polycyclic ring. A monocyclic arylene group is preferable. Specific examples of the arylene group include a phenylene group and a naphthylene group, and a phenylene group is preferable. The alkylene group, the alkenylene group, the alkynylene group, and the arylene group may further have a substituent. The substituent is preferably a group having 1 to 10 atoms. Preferred specific examples of the group having 1 to 10 atoms include an alkyl group having 1 to 3 carbon atoms [a methyl group, an ethyl group, a propyl group, and an isopropyl group], an alkenyl group having 2 or 3 carbon atoms [an ethenyl group and a propenyl group], an alkynyl group having 2 to 4 carbon atoms [an ethynyl group, a propynyl group, and the like], a cyclopropyl group, an alkoxy group having 1 or 2 carbon atoms [a methoxy group and an ethoxy group], an acyl group having 2 or 3 carbon atoms [an acetyl group and a propionyl group], an alkoxycarbonyl group having 2 or 3 carbon atoms [a methoxycarbonyl group and an ethoxycarbonyl group], an acyloxy group having 2 carbon atoms [an acetyloxy group], an acylamino group having 2 carbon atoms [an acetylamino group], a hydroxyalkyl group having 1 to 3 carbon atoms [a hydroxymethyl group, a hydroxyethyl group, and a hydroxypropyl group], an aldehyde group, a hydroxy group, a carboxy group, a sulfo group, a phospho group, a carbamoyl group, a cyano group, an isocyanate group, a mercapto group, a nitro group, a nitroxy group, an isothiocyanate group, a cyanate group, a thiocyanate group, an acetoxy group, an acetamide group, a formyl group, a formyloxy group, a formamide group, a sulfamino group, a sulfino group, a sulfamoyl group, a phosphono group, an acetyl group, a halogen atom, and an alkali metal atom.

In Formula (A), X^{A1} and X^{A2} are preferably separated by 1 to 10 atoms by L^{A1}, more preferably separated by 1 to 6 atoms, still more preferably separated by 1 to 4 atoms, even more preferably separated by 1 to 3 atoms, and particularly preferably separated by 1 or 2 atoms.

In Formula (B), X^{B1} and X^{B3} are preferably separated by 1 to 10 atoms by L^{B1}, more preferably separated by 1 to 6 atoms, still more preferably separated by 1 to 4 atoms, even more preferably separated by 1 to 3 atoms, and particularly preferably separated by 1 or 2 atoms. In addition, X^{B2} and X^{B3} are preferably separated by 1 to 10 atoms by L^{B2}, more preferably separated by 1 to 6 atoms, still more preferably separated by 1 to 4 atoms, even more preferably separated by 1 to 3 atoms, and particularly preferably separated by 1 or 2 atoms.

In Formula (C), X^{C1} and X^{C4} are preferably separated by 1 to 10 atoms by L^{C1}, more preferably separated by 1 to 6 atoms, still more preferably separated by 1 to 4 atoms, even more preferably separated by 1 to 3 atoms, and particularly preferably separated by 1 or 2 atoms. In addition, X^{C2} and X^{C4} are preferably separated by 1 to 10 atoms by L^{C2}, more preferably separated by 1 to 6 atoms, still more preferably separated by 1 to 4 atoms, even more preferably separated by 1 to 3 atoms, and particularly preferably separated by 1 or 2 atoms. In addition, X^{C3} and X^{C4} are preferably separated by 1 to 10 atoms by L^{C3}, more preferably separated by 1 to 6 atoms, still more preferably separated by 1 to 4 atoms, even more preferably separated by 1 to 3 atoms, and particularly preferably separated by 1 or 2 atoms.

The expression that X^{A1} and X^{A2} are separated by 1 to 10 atoms by L^{A1} means that the number of atoms constituting a molecular chain having the shortest distance connecting X^{A1} and X^{A2} is 1 to 10. For example, in a case of Formula (A1), X^{A1} and X^{A2} are separated by 2 atoms, and in a case of Formula (A2) and Formula (A3), X^{A1} and X^{A2} are separated by 3 atoms. The numbers added to the following structural formulae represent the order of arrangement of atoms constituting a molecular chain having the shortest distance connecting X^{A1} and X^{A2}.

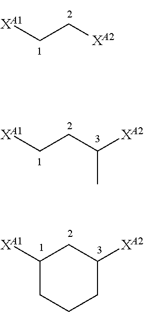

Specific examples of the multidentate ligand include ethanedithiol, 3-mercaptopropionic acid, thiosalicylic acid, thioglycolic acid, 2-aminoethanol, 2-aminoethanethiol, 2-mercaptoethanol, glycolic acid, ethylenediamine, glycine, guanidine, diethylenetriamine, tris(2-aminoethyl)amine, 4-mercaptobutanoic acid, 3-aminopropanol, 3-mercaptopropanol, N-(3-aminopropyl)-1,3-propanediamine, 3-(bis(3-aminopropyl)amino)propan-1-ol, 3-aminopropan-1-ol, 3-mercapto-2,2-bis(mercaptomethyl)-1-propanol, 1-thioglycerol, dimercaprol, 1-mercapto-2-butanol, 1-mercapto-2-pentanol, 3-mercapto-1-propanol, 2,3-dimercapto-1-propanol, diethanolamine, 2-(2-aminoethyl)aminoethanol, dimethylenetriamine, 1,1-oxybismethylamine, 1,1-thiobismethylamine, 2-[(2-aminoethyl)amino]ethanethiol, bis(2-mercaptoethyl)amine, 2-aminoethane-1-thiol, 1-amino-2-butanol, 1-amino-2-pentanol, L-cysteine, D-cysteine, 3-amino-1-propanol, L-homoserine, D-homoserine, aminohydroxyacetic acid, L-lactic acid, D-lactic acid, L-malic acid, D-malic acid, glyceric acid, 2-hydroxybutyric acid, L-tartaric acid, D-tartaric acid, 1,2-benzenedithiol, 1,3-benzenedithiol, 1,4-benzenedithiol, 2-mercaptobenzoic acid, 3-mercaptobenzoic acid, 4-mercaptobenzoic acid, 3-mercapto-2,2-bis(mercaptomethyl)-1-propanol, trimethylolpropane tris(thioglycolate), pentaerythritol tetrakis(mercaptoacetate), dipentaerythritol hexakis(3-mercaptopropionate), and dithioerythritol, and derivatives thereof.

As the organic ligand, a salt of a compound having at least one functional group selected from a carboxy group, a phospho group, a phosphonic acid group, or a sulfo group can also be used. Examples of the atom or atomic group constituting the salt of the compound having the above-described functional group include metal ions (Li⁺, Na⁺, K⁺, Ca²⁺, Mg²⁺, Zn²⁺, Cu²⁺, Ga³⁺, In³⁺, Zr⁴⁺, Hf⁴⁺, and the like), and ammonium ions. That is, examples of the salt of the compound having the above-described functional group include a metal salt of the compound having the above-described functional group and an ammonium salt of the compound having the above-described functional group.

The compound having the above-described functional group is preferably a compound having a pKa of 3 or less, and more preferably a compound having a pKa of 2.5 or less. The lower limit of the pKa of the compound having the above-described functional group is preferably −2.0 or more, more preferably −1.0 or more, and still more preferably 0.5 or more.

The molecular weight of the compound having the above-described functional group is preferably 50 to 500. The upper limit of the molecular weight is preferably 450 or less, and more preferably 400 or less.

Specific examples of the salts of compounds having the above-described functional group include metal salts and ammonium salts of compounds selected from phenylphosphonic acid, methanesulfonic acid, trifluoroacetic acid, bromoacetic acid, 3-phosphorylpropionic acid, glycine-N,N-bis(methylenephosphonic acid), 2-chloroethylphosphonic acid, methylphosphonic acid, methyl phosphate, phenyl phosphate, dimethyl phosphate, trifluoromethanesulfonic acid, and acetic acid.

The content of the ligand in the dispersion liquid is preferably 1% to 15% by mass. The lower limit thereof is preferably 2% by mass or more, and more preferably 2.5% by mass or more. The upper limit thereof is preferably 10% by mass or less, and more preferably 7% by mass or less.

In addition, the content of the ligand in the dispersion liquid is preferably 10 to 150 mg/mL. The lower limit thereof is preferably 20 mg/mL or more, and more preferably 25 mg/mL or more. The upper limit thereof is preferably 100 mg/mL or less, and more preferably 70 mg/mL or less.

In addition, the proportion of the quantum dots and the ligand is preferably such that the ligand is 10 to 100 parts by mass with respect to 100 parts by mass of the quantum dots. The lower limit thereof is preferably 20 parts by mass or more, and more preferably 30 parts by mass or more. The upper limit thereof is preferably 80 parts by mass or less, and more preferably 70 parts by mass or less.

### (Organic Solvent)

The dispersion liquid according to the embodiment of the present invention contains an organic solvent. The organic solvent is not particularly limited, but is preferably a solvent which is difficult to dissolve the quantum dots and is easy to dissolve the ligand.

The organic solvent may be any of a polar solvent or a nonpolar solvent, but is preferably a polar solvent and more preferably a polar solvent having an amide group from the viewpoint that the dispersibility of the quantum dots can be further improved.

The boiling point of the organic solvent is preferably 60 °C to 250 °C. The lower limit thereof is preferably 70 °C or higher, and more preferably 80 °C or higher. The upper limit thereof is preferably 200 °C or lower, and more preferably 190 °C or lower.

Specific examples of the organic solvent include alkanes [n-hexane, n-octane, and the like], benzene, toluene, N,N-dimethylformamide, dimethyl sulfoxide, N-methylformamide, N,N-dimethylacetamide, propylene carbonate, and ethylene glycol, and N,N-dimethylformamide, dimethyl sulfoxide, or N-methylformamide is preferable.

The content of the organic solvent in the dispersion liquid is preferably 50% to 99% by mass, more preferably 70% to 99% by mass, and still more preferably 85% to 98% by mass.

The organic solvent contained in the dispersion liquid may be only one kind or may be a mixed solvent obtained by mixing two or more kinds thereof. In a case where two or more kinds of organic solvents are contained, the total amount thereof is preferably within the above-described range.

### <Method for Producing Photoelectric Conversion Film>

The method for producing a photoelectric conversion film according to the embodiment of the present invention includes
a step of applying the above-described dispersion liquid according to the embodiment of the present invention onto a support to form a composition layer, and
a step of drying the composition layer.

The shape, structure, size, and the like of the support to which the dispersion liquid is applied are not particularly limited, and can be appropriately selected according to the purpose. The structure of the support may be a monolayer structure or a laminated structure. As the support, for example, a support formed of an inorganic material such as silicon, glass, or yttria-stabilized zirconia (YSZ), a resin, a resin composite material, or the like can be used. In addition, an electrode, an insulating film, or the like may be formed on the support. In this case, the dispersion liquid is also applied onto the electrode or the insulating film on the support.

The method of applying the dispersion liquid is not particularly limited. Examples of the method include a coating method such as a spin coating method, a dipping method, an inkjet method, a dispenser method, a screen printing method, a relief printing method, an intaglio printing method, or a spray coating method.

After the composition layer is formed, the composition layer is dried. By performing the drying, the solvent remaining in the composition layer can be removed.

The drying temperature is preferably 50 °C to 150 °C. The upper limit of the drying temperature is preferably 120 °C or lower and more preferably 100 °C or lower. The lower limit of the drying temperature is preferably 55 °C or higher and more preferably 60 °C or higher.

The drying time is preferably 1 to 300 minutes. The upper limit of the drying time is preferably 200 minutes or shorter and more preferably 100 minutes or shorter. The lower limit of the drying time is preferably 2 minutes or longer and more preferably 5 minutes or longer.

In the method for producing a photoelectric conversion film according to the embodiment of the present invention, the step of forming a composition layer and the step of drying the composition layer may be alternately repeated a plurality of times.

In the method for producing a photoelectric conversion film according to the embodiment of the present invention, after the step of drying the composition layer, a step of applying a ligand solution to the composition layer after drying may be performed. By performing this step, the ligand coordinated to the quantum dot can be exchanged with the ligand contained in the ligand solution, or the ligand contained in the ligand solution can be coordinated to the quantum dot to suppress the occurrence of surface defects of the quantum dot.

Examples of the ligand contained in the ligand solution include the ligands described as the ligands used in the dispersion liquid according to the embodiment of the present invention. The ligand contained in the ligand solution may be the same as or different from the ligand contained in the dispersion liquid. The ligand solution may contain only one kind of ligand or may contain two or more kinds of ligands. In addition, in the step of applying the ligand solution, two or more kinds of ligand solutions may be used.

The solvent contained in the ligand solution is preferably appropriately selected according to the kind of the ligand contained in the ligand solution, and is preferably a solvent that easily dissolves the ligand. In addition, the solvent contained in the ligand solution is preferably an organic solvent having a high permittivity. Specific examples thereof include ethanol, acetone, methanol, acetonitrile, dimethylformamide, dimethyl sulfoxide, butanol, and propanol. In addition, the solvent contained in the ligand solution is preferably a solvent that is difficult to remain in the photoelectric conversion film to be formed. From the viewpoint of being easily dried and easily removed by washing, an alcohol, a ketone, or a nitrile having a low boiling point is preferable, and methanol, ethanol, acetone, or acetonitrile is more preferable.

The method of applying the ligand solution is the same as the method of applying the dispersion liquid onto the support, and the same applies to the preferred aspect thereof.

In a case where the step of applying the ligand solution is performed, a step of bringing the rinsing liquid into contact with the film after the application of the ligand solution to perform rinsing (rinsing step) may be performed. By performing the rinsing step, it is possible to remove the excessive ligand contained in the film or the ligand desorbed from the quantum dot. In addition, it is possible to remove the remaining solvent and other impurities. As the rinsing liquid, an aprotic solvent is preferable from the viewpoint that the excessive ligand contained in the film or the ligand desorbed from the quantum dot is more easily and effectively removed, and the film surface shape is easily kept homogeneous by rearranging the surface of the quantum dot. Specific examples of the aprotic solvent include acetonitrile, acetone, methyl ethyl ketone, methyl isobutyl ketone, cyclopentanone, diethyl ether, tetrahydrofuran, cyclopentyl methyl ether, dioxane, ethyl acetate, butyl acetate, propylene glycol monomethyl ether acetate, hexane, octane, cyclohexane, benzene, toluene, chloroform, carbon tetrachloride, and dimethylformamide, and acetonitrile or tetrahydrofuran is preferable, and acetonitrile is more preferable.

In addition, the rinsing step may be performed a plurality of times using two or more kinds of rinsing liquids having different polarities (relative permittivities). For example, it is preferable that the rinsing is first performed using a rinsing liquid having a high relative permittivity (also referred to as a first rinsing liquid), and then the rinsing is performed using a rinsing liquid having a lower relative permittivity than the first rinsing liquid (also referred to as a second rinsing liquid). The relative permittivity of the first rinsing liquid is preferably 15 to 50, more preferably 20 to 45, and still more preferably 25 to 40. The relative permittivity of the second rinsing liquid is preferably 1 to 15, more preferably 1 to 10, and still more preferably 1 to 5.

The photoelectric conversion film can be manufactured through such steps. The obtained photoelectric conversion film can be used for a photodetector element or an image sensor. Since the photoelectric conversion film obtained using the dispersion liquid according to the embodiment of the present invention has excellent sensitivity to light having a wavelength in the infrared region, the photodetector element using the photoelectric conversion film is preferably used as a photodetector element that detects light having a wavelength in the infrared region. Therefore, the photoelectric conversion film is preferably used as a photoelectric conversion film for an infrared photodetector element.

The light having a wavelength in the above-described infrared region is preferably light having a wavelength of more than 700 nm, more preferably light having a wavelength of 800 nm or more, and still more preferably light having a wavelength of 900 nm or more. In addition, the light having a wavelength in the infrared region is preferably light having a wavelength of 2,000 nm or less, and more preferably light having a wavelength of 1,600 nm or less.

A total content of the quantum dots and the ligand in the photoelectric conversion film is preferably 60% by mass or more, more preferably 70% by mass or more, still more preferably 80% by mass or more, even more preferably 90% by mass or more, and particularly preferably 95% by mass or more. An upper limit thereof can be set to 100% by mass or less.

### <Method for Producing Photodetector Element>

The photodetector element according to the embodiment of the present invention includes the above-described method for producing a photoelectric conversion film according to the embodiment of the present invention. Specifically, it is preferable to form a photoelectric conversion film of a photodetector element using the above-described method for producing a photoelectric conversion film.

Examples of the type of the photodetector element include a photoconductive type photodetector element and a photodiode-type photodetector element. Among these, a photodiode-type photodetector element is preferable from the viewpoint that a high signal-to-noise ratio (SN ratio) is easily obtained.

Since the photoelectric conversion film obtained by the present invention has excellent sensitivity to light having a wavelength in the infrared region, the photodetector element is preferably used as a photodetector element that detects light having a wavelength in the infrared region. That is, the above-described photodetector element is preferably used as an infrared photodetector element.

The photodetector element may be a photodetector element that simultaneously detects light having a wavelength in the infrared region and light having a wavelength in the visible region (preferably, light having a wavelength in a range of 400 to 700 nm).

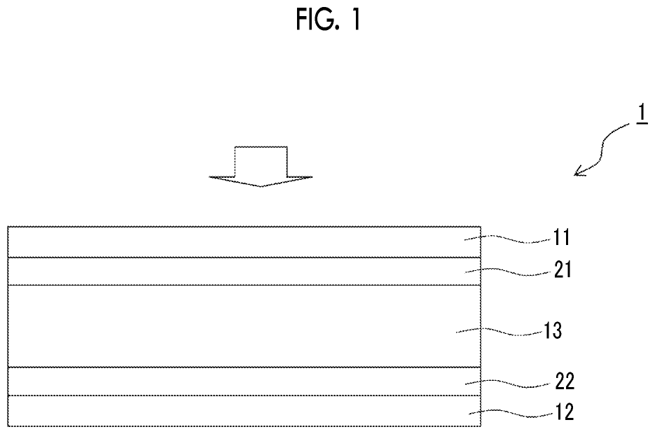

FIG. 1 shows an embodiment of the photodetector element. FIG. 1 is a view showing an embodiment of a photodiode-type photodetector element. An arrow in the drawing represents incident light on the photodetector element. A photodetector element 1 shown in FIG. 1 includes a second electrode 12, a first electrode 11 provided to face the second electrode 12, a photoelectric conversion film 13 provided between the second electrode 12 and the first electrode 11, an electron transport layer 21 provided between the first electrode 11 and the photoelectric conversion film 13, and a hole transport layer 22 provided between the second electrode 12 and the photoelectric conversion film 13. The photodetector element 1 shown in FIG. 1 is used such that light is incident from above the first electrode 11. Although not shown, a transparent substrate may be disposed on a surface of the first electrode 11 on a light-incident side. Examples of the type of the transparent substrate include a glass substrate, a resin substrate, and a ceramic substrate.

### (First Electrode)

The first electrode 11 is preferably a transparent electrode formed of a conductive material that is substantially transparent to a wavelength of light to be detected by the photodetector element. In the present specification, the expression “substantially transparent” means that a transmittance of light is 50% or more, preferably 60% or more, and more preferably 80% or more. Examples of materials of the first electrode 11 include a conductive metal oxide. Specific examples thereof include tin oxide, zinc oxide, indium oxide, indium tungsten oxide, indium zinc oxide (IZO), indium tin oxide (ITO), and fluorine-doped tin oxide (FTO).

A film thickness of the first electrode 11 is not particularly limited, and is preferably 0.01 to 100 μm, more preferably 0.01 to 10 μm, and still more preferably 0.01 to 1 μm. The film thickness of each layer can be measured by observing a cross section of the photodetector element 1 using a scanning electron microscope (SEM) or the like.

### (Electron Transport Layer)

The electron transport layer 21 is a layer having a function of transporting electrons generated in the photoelectric conversion film 13 to the electrode. The electron transport layer is also referred to as a hole blocking layer. The electron transport layer is formed of an electron transport material capable of exhibiting the function.

Examples of the electron transport material include a fullerene compound such as [6,6]-phenyl-C61-butyric acid methyl ester (PC₆₁BM), a perylene compound such as perylenetetracarboxylic diimide, tetracyanoquinodimethane, titanium oxide, tin oxide, zinc oxide, indium oxide, indium tungsten oxide, indium zinc oxide, indium tin oxide, and fluorine-doped tin oxide. The electron transport material may be particles. The electron transport material is preferably zinc oxide. In addition, from the viewpoint of reducing the organic residual component and increasing the contact area with the photoelectric conversion film, the zinc oxide is preferably particles (zinc oxide particles).

The zinc oxide may be zinc oxide doped with a metal atom other than Zn. Hereinafter, the zinc oxide doped with a metal atom other than Zn is also referred to as doped zinc oxide.

The metal atom other than Zn in the doped zinc oxide is preferably a monovalent to trivalent metal atom, more preferably includes at least one selected from Li, Mg, Al, or Ga, still more preferably Li, Mg, Al, or Ga, and particularly preferably Li or Mg.

In the doped zinc oxide, a proportion of the metal atom other than Zn to the total of Zn and the metal atom other than Zn is preferably 1 atom % or more, more preferably 2 atom % or more, and still more preferably 4 atom % or more. From the viewpoint of suppressing an increase in crystal defects, the upper limit thereof is preferably 20 atom % or less, more preferably 15 atom % or less, and still more preferably 12 atom % or less. The proportion of the metal atom other than Zn in the doped zinc oxide can be measured by a high-frequency inductively coupled plasma (ICP) method.

The average particle diameter of the zinc oxide particles is preferably 2 to 30 nm. In addition, the upper limit value of the average particle diameter of the zinc oxide particles is preferably 20 nm or less, and more preferably 15 nm or less. In a case where the average particle diameter of the zinc oxide particles is within the above-described range, a film having a large contact area with the photoelectric conversion film and having high flatness is easily obtained. In the present specification, the value of the average particle diameter of the zinc oxide particles is an average value of 10 particle diameters randomly selected. For the measurement of the particle diameter of the zinc oxide particles, a transmission electron microscope may be used.

The electron transport layer may be a single-layer film or a laminated film having two or more layers. The thickness of the electron transport layer is preferably 10 to 1,000 nm. The upper limit thereof is preferably 800 nm or less. The lower limit thereof is preferably 20 nm or more and more preferably 50 nm or more. In addition, the thickness of the electron transport layer is preferably 0.05 to 10 times, more preferably 0.1 to 5 times, and still more preferably 0.2 to 2 times the thickness of the photoelectric conversion film 13.

The above-described electron transport layer may be subjected to an ultraviolet ozone treatment. In particular, in a case where the electron transport layer is a layer consisting of nanoparticles, it is desirable to perform the ultraviolet ozone treatment. By performing the ultraviolet ozone treatment, the wettability of the quantum dot dispersion liquid with respect to the electron transport layer is improved, and the residual organic matter in the electron transport layer can be decomposed or removed, so that high element performance can be obtained. The wavelength of the ultraviolet rays to be irradiated can be selected in a range of a wavelength of 100 to 400 nm. In particular, from the reason that the above-described effect is easily obtained and damage to the film due to excessive irradiation can be avoided, the peak intensity is preferably in a wavelength range of 200 to 300 nm and more preferably in a wavelength range of 240 to 270 nm. The irradiation intensity of the ultraviolet rays is not particularly limited, but from the reason that the above-described effect is easily obtained and damage to the film due to excessive irradiation can be avoided, the irradiation intensity is preferably 1 to 100 mW/cm² and more preferably 10 to 50 mW/cm². The treatment time is not particularly limited, but from the same reason, the treatment time is preferably 1 to 60 minutes, more preferably 1 to 20 minutes, and still more preferably 3 to 15 minutes.

### (Photoelectric Conversion Film)

The photoelectric conversion film 13 is composed of a quantum dot film formed of the above-described dispersion liquid according to the embodiment of the present invention. The photoelectric conversion film 13 can be formed by the above-described method.

The thickness of the photoelectric conversion film 13 is preferably 10 to 1,000 nm. The lower limit of the thickness is preferably 20 nm or more and more preferably 30 nm or more. The upper limit of the thickness is preferably 600 nm or less, more preferably 550 nm or less, still more preferably 500 nm or less, and particularly preferably 450 nm or less. The refractive index of the photoelectric conversion film 13 with respect to light having a wavelength to be detected by the photodetector element can be set to 1.5 to 5.0.

### (Hole Transport Layer)

The hole transport layer 22 is a layer having a function of transporting holes generated in the photoelectric conversion film 13 to the electrode. The hole transport layer is also referred to as an electron blocking layer.

The hole transport layer 22 is formed of a hole transport material capable of exhibiting the function. Examples of the hole transport material include PEDOT:PSS (a complex of poly(3,4-ethylenedioxythiophene) and poly(4-styrenesulfonic acid)), PTB7 (poly{4,8-bis[(2-ethylhexyl)oxy]benzo[1,2-b:4,5-b′]dithiophene-2,6-diyl-alt-3-fluoro-2-[(2-ethylhexyl)carbonyl]thieno[3,4-b]thiophene-4,6-diyl}), PTB7-Th (poly([2,6′-4,8-di(5-ethylhexylthienyl)benzo[1,2-b;3,3-b]dithiophene]{3-fluoro-2-[(2-ethylhexyl)carbonyl]thieno[3,4-b]thiophenediyl})), poly(3-hexylthiophene-2,5-diyl), poly(3-n-octyloxythiophene), poly(9,9′-dioctyl-fluorene-co-bithiophene), poly(3,3″′-dodecyl-quaterthiophene), poly(3,6-dioctylthieno[3,2-b]thiophene), poly(2,5-bis(3-decylthiophen-2-yl)thieno[3,2-b]thiophene), poly(3,4-didecylthiophene-co-thieno[3,2-b]thiophene), poly(3,6-dioctylthieno[3,2-b]thiophene-co-thieno[3,2-b]thiophene), poly(3,6-dioctylthieno[3,2-b]thiophene-co-thiophene), poly(3,6-dioctylthieno[3,2-b]thiophene-co-bithiophene), and PC₇₁BM ([6,6]-phenyl-C71-butyric acid methyl ester). In addition, an organic hole transport material described in paragraphs 0209 to 0212 of JP2001-291534A can also be used. In addition, quantum dots can also be used as the hole transport material. Examples of the quantum dot material constituting the quantum dots include nanoparticles (particles having a size of 0.5 nm or more and less than 100 nm) of a general semiconductor crystal [a) a group IV semiconductor, b) a group IV-IV, group III-V, or group II-VI compound semiconductor, and c) a compound semiconductor consisting of a combination of three or more of group IL, group III, group IV, group V, and group VI elements]. Specific examples thereof include semiconductor materials having a relatively narrow band gap, such as PbS, PbSe, PbSeS, InN, Ge, InAs, InGaAs, CuInS, CuInSe, CuInGaSe, InSb, HgTe, HgCdTe, Ag₂S, Ag₂Se, Ag₂Te, SnS, SnSe, SnTe, Si, and InP. A ligand may be coordinated to the surface of the quantum dot.

The thickness of the hole transport layer 22 is preferably 5 to 100 nm. The lower limit thereof is preferably 10 nm or more. The upper limit thereof is preferably 50 nm or less and more preferably 30 nm or less.

### (Second Electrode)

The second electrode 12 is preferably formed of a metal material containing at least one metal atom selected from Ag, Au, Pt, Ir, Pd, Cu, Pb, Sn, Zn, Ti, W, Mo, Ta, Ge, Ni, Al, Cr, and In. In a case where the second electrode 12 is formed of such a metal material, a photodetector element having a high external quantum efficiency and a low dark current can be obtained. In addition, the above-described conductive metal oxide, carbon material, conductive polymer, or the like can also be used for the second electrode 12. The carbon material may be any material having conductivity, and examples thereof include fullerene, a carbon nanotube, graphite, and graphene.

From the viewpoint that the electron blocking property by the hole transport layer is increased and holes generated in the element are easily collected, the work function of the second electrode 12 is preferably 4.6 eV or more, more preferably 4.8 to 5.7 eV, and still more preferably 4.9 to 5.3 eV.

The film thickness of the second electrode 12 is not particularly limited, and is preferably 0.01 to 100 μm, more preferably 0.01 to 10 μm, and still more preferably 0.01 to 1 μm.

### (Charge Extraction Layer)

Although not shown, the photodetector element may have a charge extraction layer between the second electrode 12 and the hole transport layer 22. In a case where the charge extraction layer is provided, a high external quantum efficiency can be obtained at a low applied voltage.

Examples of a material for forming the charge extraction layer include a metal oxide and an organic semiconductor, and a metal oxide is preferable. Examples of the metal oxide include molybdenum oxide, titanium oxide, vanadium oxide, chromium oxide, cobalt oxide, nickel oxide, copper oxide, zirconium oxide, silver oxide, tantalum oxide, and tungsten oxide, and molybdenum oxide is preferable. Examples of the organic semiconductor include a polythiophene compound. Specific examples of the polythiophene compound include the above-described materials. The charge extraction layer may be a single-layer film or a laminated film of two or more layers.

The film thickness of the charge extraction layer is preferably 1 to 100 nm. The lower limit thereof is preferably 5 nm or more. The upper limit thereof is preferably 50 nm or less.

(Blocking layer)

Although not shown, the photodetector element may have a blocking layer between the first electrode 11 and the electron transport layer 21. The blocking layer is a layer having a function of preventing a reverse current. The blocking layer is also referred to as a short-circuit prevention layer. Examples of a material for forming the blocking layer include silicon oxide, magnesium oxide, aluminum oxide, calcium carbonate, cesium carbonate, polyvinyl alcohol, polyurethane, titanium oxide, tin oxide, zinc oxide, niobium oxide, and tungsten oxide. The blocking layer may be a single-layer film or a laminated film of two or more layers. The film thickness of the blocking layer is preferably 5 to 100 nm. The lower limit thereof is preferably 10 nm or more. The upper limit thereof is preferably 50 nm or less, and more preferably 30 nm or less.

In the photodetector element, it is preferable that a wavelength λ of light to be detected by the photodetector element and an optical path length Lx of the light having the wavelength λ from a surface of the second electrode 12 on the photoelectric conversion film 13 side to a surface of the photoelectric conversion film 13 on the first electrode 11 side satisfy a relationship of the following Expression (1-1), and it is more preferable that the wavelength λ and the optical path length L^{λ} satisfy a relationship of the following Expression (1-2). In a case where the wavelength λ and the optical path length L^{λ} satisfy such a relationship, in the photoelectric conversion film 13, a phase of light (incident light) incident from the first electrode 11 side and a phase of light (reflected light) reflected on the surface of the second electrode 12 can be aligned, and as a result, the light is strengthened by an optical interference effect, and a higher external quantum efficiency can be obtained.

0.05+m/2≤L^{λ}/λ≤0.35+m/2 (1-1)

0.10+m/2≤L^{λ}/λ≤0.30+m/2 (1-2)

In the expression, λ is a wavelength of light to be detected by the photodetector element,
L^{λ} is an optical path length of the light having the wavelength λ from a surface of the second electrode 12 on the photoelectric conversion film 13 side to a surface of the photoelectric conversion film 13 on the first electrode 11 side, and
m is an integer of 0 or more.

m is preferably an integer of 0 to 4, more preferably an integer of 0 to 3, and still more preferably an integer of 0 to 2. According to this aspect, the charge transport characteristics of holes, electrons, and the like are favorable, and the external quantum efficiency of the photodetector element can be further increased.

Here, the optical path length means a value obtained by multiplying a physical thickness of a substance through which light is transmitted by a refractive index. In a case of the photoelectric conversion film 13 as an example, in a case where a thickness of the photoelectric conversion film is denoted by d¹ and a refractive index of the photoelectric conversion film with respect to light having a wavelength λ¹ is denoted by N¹, an optical path length of the light having the wavelength λ¹ transmitted through the photoelectric conversion film 13 is N¹×d¹. In a case where the photoelectric conversion film 13 or the hole transport layer 22 is composed of a laminated film of two or more layers or in a case where an interlayer is present between the hole transport layer 22 and the second electrode 12, an integrated value of the optical path lengths of the respective layers is the optical path length L^{λ}.

### <Method for Producing Image Sensor>

The method for producing an image sensor according to the embodiment of the present invention includes the above-described method for producing a photoelectric conversion film according to the embodiment of the present invention. Specifically, it is preferable that the photoelectric conversion film of the image sensor is formed by using the above-described method for producing a photoelectric conversion film.

Since the photoelectric conversion film obtained by the present invention has excellent sensitivity to light having a wavelength in the infrared region, the image sensor using the photoelectric conversion film can be particularly preferably used as an infrared sensor. In addition, the image sensor can be preferably used as an image sensor that senses light having a wavelength of 900 to 2,000 nm, and can be more preferably used as an image sensor that senses light having a wavelength of 900 to 1,600 nm.

The configuration of the image sensor is not particularly limited as long as the image sensor includes a photodetector element and functions as an image sensor. Examples of the photodetector element include those described above.

The image sensor may include an infrared transmitting filter layer. The infrared transmitting filter layer is preferably a layer having low transmittance of light in a wavelength range of a visible region, and more preferably a layer having an average transmittance of light in a wavelength range of 400 to 650 nm of 10% or less, still more preferably 7.5% or less, and particularly preferably 5% or less.

Examples of the infrared transmitting filter layer include a layer formed of a resin film containing a coloring material. Examples of the coloring material include chromatic coloring materials such as a red coloring material, a green coloring material, a blue coloring material, a yellow coloring material, a purple coloring material, and an orange coloring material, and a black coloring material. It is preferable that the coloring material contained in the infrared transmitting filter layer forms a black color by a combination of two or more chromatic coloring materials, or contains a black coloring material. In a case where black is formed by a combination of two or more chromatic coloring materials, examples of the combination of the chromatic coloring materials include the following aspects (C1) to (C7).
(C1) An aspect containing a red coloring material and a blue coloring material.
(C2) An aspect containing a red coloring material, a blue coloring material, and a yellow coloring material.
(C3) An aspect containing a red coloring material, a blue coloring material, a yellow coloring material, and a purple coloring material.
(C4) An aspect containing a red coloring material, a blue coloring material, a yellow coloring material, a purple coloring material, and a green coloring material.
(C5) An aspect containing a red coloring material, a blue coloring material, a yellow coloring material, and a green coloring material.
(C6) An aspect containing a red coloring material, a blue coloring material, and a green coloring material.
(C7) An aspect containing a yellow coloring material and a purple coloring material.

The above-described chromatic coloring material may be a pigment or a dye. A pigment and a dye may be contained. The black coloring material is preferably an organic black coloring material. Examples of the organic black coloring material include a bisbenzofuranone compound, an azomethine compound, a perylene compound, and an azo compound.

The infrared transmitting filter layer may further contain an infrared absorber. By containing the infrared absorber in the infrared transmitting filter layer, the wavelength of light to be transmitted can be shifted further to the longer wavelength side. Examples of the infrared absorber include a pyrrolo pyrrole compound, a cyanine compound, a squarylium compound, a phthalocyanine compound, a naphthalocyanine compound, a quaterrylene compound, a merocyanine compound, a croconium compound, an oxonol compound, an iminium compound, a dithiol compound, a triarylmethane compound, a pyromethene compound, an azomethine compound, an anthraquinone compound, a dibenzofuranone compound, a dithiolene metal complex, a metal oxide, and a metal boride.

The spectral characteristics of the infrared transmitting filter layer can be appropriately selected according to the use of the image sensor. Examples thereof include a filter layer that satisfies any of the following spectral characteristics (1) to (5).
(1): A filter layer in which a maximum value of a transmittance of light in a thickness direction of a film in a wavelength range of 400 to 750 nm is 20% or less (preferably 15% or less and more preferably 10% or less), and a minimum value of the transmittance of light in the thickness direction of the film in a wavelength range of 900 to 1500 nm is 70% or more (preferably 75% or more and more preferably 80% or more).
(2): A filter layer in which a maximum value of a transmittance of light in a thickness direction of a film in a wavelength range of 400 to 830 nm is 20% or less (preferably 15% or less and more preferably 10% or less), and a minimum value of the transmittance of light in the thickness direction of the film in a wavelength range of 1000 to 1500 nm is 70% or more (preferably 75% or more and more preferably 80% or more).
(3): A filter layer in which a maximum value of a transmittance of light in a thickness direction of a film in a wavelength range of 400 to 950 nm is 20% or less (preferably 15% or less and more preferably 10% or less), and a minimum value of the transmittance of light in the thickness direction of the film in a wavelength range of 1100 to 1500 nm is 70% or more (preferably 75% or more and more preferably 80% or more).
(4): A filter layer in which a maximum value of a transmittance of light in a thickness direction of a film in a wavelength range of 400 to 1100 nm is 20% or less (preferably 15% or less and more preferably 10% or less), and a minimum value of the transmittance of light in a wavelength range of 1400 to 1500 nm is 70% or more (preferably 75% or more and more preferably 80% or more).
(5): A filter layer in which a maximum value of a transmittance of light in a thickness direction of a film in a wavelength range of 400 to 1300 nm is 20% or less (preferably 15% or less and more preferably 10% or less), and a minimum value of the transmittance of light in a wavelength range of 1600 to 2000 nm is 70% or more (preferably 75% or more and more preferably 80% or more).

In addition, as the infrared transmitting filter, films described in JP2013-077009A, JP2014-130173A, JP2014-130338A, WO2015/166779A, WO2016/178346A, WO2016/190162A, WO2018/016232A, JP2016-177079A, JP2014-130332A, and WO2016/027798A can be used. As the infrared transmitting filter, two or more filters may be used in combination, or a dual bandpass filter that transmits two or more specific wavelength ranges with one filter may be used.

The image sensor may include an infrared cut filter for the purpose of improving various performances such as noise reduction. Specific examples of the infrared cut filter include filters described in WO2016/186050A, WO2016/035695A, JP6248945B, WO2019/021767A, JP2017-067963A, and JP6506529B.

The image sensor may include a dielectric multi-layer film. Examples of the dielectric multi-layer film include a film in which a dielectric thin film having a high refractive index (high-refractive-index material layer) and a dielectric thin film having a low refractive index (low-refractive-index material layer) are alternately laminated in a plurality of layers. The number of laminated dielectric thin films in the dielectric multi-layer film is not particularly limited, but is preferably 2 to 100 layers, more preferably 4 to 60 layers, and still more preferably 6 to 40 layers. As a material used for forming the high-refractive-index material layer, a material having a refractive index of 1.7 to 2.5 is preferable. Specific examples thereof include Sb₂O₃, Sb₂S₃, Bi₂O₃, CeO₂, CeF₃, HfO₂, La₂O₃, Nd₂O₃, Pr₆O₁₁, Sc₂O₃, SiO, Ta₂O₅, TiO₂, TlCl, Y₂O₃, ZnSe, ZnS, and ZrO₂. As a material used for forming the low-refractive-index material layer, a material having a refractive index of 1.2 to 1.6 is preferable. Specific examples thereof include Al₂O₃, BiF₃, CaF₂, LaF₃, PbCl₂, PbF₂, LiF, MgF₂, MgO, NdF₃, SiO₂, Si₂O₃, NaF, ThO₂, ThF₄, and Na₃AlF₆. A method for forming the dielectric multi-layer film is not particularly limited, and examples thereof include a vacuum evaporation method such as ion plating or ion beam, a physical vapor deposition method (PVD method) such as sputtering, and a chemical vapor deposition method (CVD method). In a case where a wavelength of light to be cut off is λ (nm), a thickness of each layer of the high-refractive-index material layer and the low-refractive-index material layer is preferably 0.1λ to 0.5λ. As a specific example of the dielectric multi-layer film, for example, films described in JP2014-130344A and JP2018-010296A can be used.

In the dielectric multi-layer film, it is preferable that a transmission wavelength range is provided in an infrared range (preferably a wavelength range exceeding a wavelength of 700 nm, more preferably a wavelength range exceeding a wavelength of 800 nm, and still more preferably a wavelength range exceeding a wavelength of 900 nm). A maximum transmittance in the transmission wavelength range is preferably 70% or more, more preferably 80% or more, and still more preferably 90% or more. In addition, a maximum transmittance in the light-blocking wavelength range is preferably 20% or less, more preferably 10% or less, and still more preferably 5% or less. In addition, an average transmittance in the transmission wavelength range is preferably 60% or more, more preferably 70% or more, and still more preferably 80% or more. In addition, in a case where a wavelength at which the maximum transmittance is exhibited is defined as a central wavelength λₜ₁, a wavelength range of the transmission wavelength range is preferably a central wavelength λₜ₁±100 nm, more preferably a central wavelength λₜ₁±75 nm, and still more preferably a central wavelength λₜ₁±50 nm.

The dielectric multi-layer film may have only one transmission wavelength range (preferably a transmission wavelength range in which the maximum transmittance is 90% or more), or may have a plurality of transmission wavelength ranges.

The image sensor may include a color separation filter layer. Examples of the color separation filter layer include a filter layer including a colored pixel. Examples of the type of the colored pixel include a red pixel, a green pixel, a blue pixel, a yellow pixel, a cyan pixel, and a magenta pixel. The color separation filter layer may include colored pixels of two or more colors, or may include only one color. The color separation filter layer can be appropriately selected depending on the use application and the purpose. For example, a filter described in WO2019/039172A can be used.

In addition, in a case where the color separation layer includes colored pixels of two or more colors, the colored pixels of each color may be adjacent to each other, or a partition wall may be provided between the colored pixels. A material of the partition wall is not particularly limited. Examples thereof include an organic material such as a siloxane resin or a fluororesin, and inorganic particles such as silica particles. In addition, the partition wall may be formed of a metal such as tungsten or aluminum.

In a case where the image sensor includes an infrared transmitting filter layer and a color separation layer, it is preferable that the color separation layer is provided on an optical path different from that of the infrared transmitting filter layer. In addition, it is also preferable that the infrared transmitting filter layer and the color separation layer are two-dimensionally arranged. The fact that the infrared transmitting filter layer and the color separation layer are two-dimensionally arranged means that at least a part of each of the infrared transmitting filter layer and the color separation layer is present on the same plane.

The image sensor may include an interlayer such as a planarizing layer, a base layer, and an adhesion layer, an anti-reflection film, a lens, and the like. As the anti-reflection film, for example, a film produced from a composition described in WO2019/017280A can be used. As the lens, for example, a structure described in WO2018/092600A can be used.

### Examples

Hereinafter, the present invention will be described in more detail with reference to Examples. The materials, the used amounts, the proportions, the treatment contents, the treatment procedures, and the like shown in the following examples can be appropriately changed without departing from the gist of the present invention. Therefore, the scope of the present invention is not limited to the specific examples shown below.

### <Production of Dispersion Liquid>

1 mL of an octane dispersion liquid of quantum dots (concentration of quantum dots: 50 mg/mL, concentration of oleic acid: 50 mg/mL) having oleic acid coordinated on the surface thereof, which is described in the following table, 0.5 g of a ligand described in the following table (0.25 g of each of the ligands described in the following table in Examples 18 and 116), and 5 mL of an organic solvent described in the following table (2.5 mL of each of the solvents described in the following table in Examples 19 and 117) were weighed in a centrifugal separation tube, and the mixture was vigorously stirred for 10 minutes.

Next, 30 mL of hexane was added thereto, the mixture was vigorously stirred for 1 minute, and then an operation of removing an upper hexane layer was repeated twice. Next, an excessive amount of toluene was added thereto, and centrifugal separation was performed at 4,000 rpm for 5 minutes. The obtained precipitate was vacuum-dried for 30 minutes, 0.5 mL of an organic solvent described in the following table (0.25 mL of each of the solvents described in the following table in Examples 19 and 117) and water were added thereto, and the mixture was stirred for 2 hours to obtain a dispersion liquid. All of the above-described operations were performed under nitrogen. The content of water in the dispersion liquid is described in the column of “Moisture content” in the following table. The content of water (moisture content) in the dispersion liquid was adjusted by the formulation amount of water. In addition, the content of water (moisture content) in the dispersion liquid was measured by a Karl Fischer method. Specifically, the moisture content in the dispersion liquid was measured using a Karl Fischer moisture meter (KF-06 manufactured by Mitsubishi Chemical Corporation), and calculated from the following expression.

Content of water in dispersion liquid (moisture content)=(moisture content/dispersion liquid mass)×100

### <Evaluation of Dispersibility>

The obtained dispersion liquid was allowed to stand at 25 °C for 2 days, 1 week, or 1 month under nitrogen, and then the presence or absence of aggregates was visually observed to evaluate the dispersibility.
A: No coagulation was observed even after standing for 1 month.
B: Slight coagulation was observed after standing for 1 month, but no coagulation was observed after standing for 1 week.
C: No coagulation was observed after standing for 2 days, but coagulation was observed after standing for 1 week.
D: In the production step of the dispersion liquid, the precipitate after centrifugal separation was not dispersed.

TABLE 1

| | Quantum dots | | | | | | | | | |
|---|---|---|---|---|---|---|---|---|---|---|
| | | | | Average | | | | | | |
| | | | | primary | | | | | | |
| | | Band | | particle | | Ligand | | | Moisture | |
| | | gap | λmax | diameter | Content | | Content | Organic | content | |
| | Type | (eV) | (nm) | (nm) | (mass %) | Type | (mass %) | solvent | (mass %) | dispersibility |
| Example 1 | InAs | 1.35 | 940 | 3.9 | 75 | L1-1 | 23 | S-1 | 0.01 | A |
| Example 2 | InAs | 1.35 | 940 | 3.9 | 75 | L1-1 | 23 | S-1 | 0.1 | A |
| Example 3 | InAs | 1.35 | 940 | 3.9 | 75 | L1-1 | 23 | S-1 | 0.005 | B |
| Example 4 | InAs | 1.35 | 940 | 3.9 | 75 | L1-1 | 23 | S-1 | 0.2 | B |
| Example 5 | InAs | 1.35 | 940 | 3.9 | 75 | L2-1 | 23 | S-1 | 0.01 | A |
| Example 6 | InAs | 1.35 | 940 | 3.9 | 75 | L2-2 | 23 | S-1 | 0.01 | A |
| Example 7 | InAs | 1.35 | 940 | 3.9 | 75 | L1-1 | 23 | S-2 | 0.01 | B |
| Example 8 | InAs | 1.35 | 940 | 3.9 | 75 | L1-1 | 23 | S-3 | 0.01 | B |
| Example 9 | InAs | 1.35 | 940 | 3.9 | 75 | L2-3 | 23 | S-1 | 0.01 | B |
| Example 10 | InAs | 1.35 | 940 | 3.9 | 75 | L2-4 | 23 | S-1 | 0.01 | A |
| Example 11 | InAs | 1.35 | 940 | 3.9 | 75 | L2-5 | 23 | S-1 | 0.01 | A |
| Example 12 | InAs | 1.35 | 940 | 3.9 | 75 | L2-6 | 23 | S-1 | 0.01 | B |
| Example 13 | InAs | 1.35 | 940 | 3.9 | 75 | L2-7 | 23 | S-1 | 0.01 | B |
| Example 14 | InAs | 1.35 | 940 | 3.9 | 75 | L1-2 | 23 | S-1 | 0.01 | A |
| Example 15 | InAs | 1.35 | 940 | 3.9 | 75 | L1-3 | 23 | S-1 | 0.01 | A |
| Example 16 | PbS | 1.35 | 940 | 2.1 | 75 | L1-1 | 23 | S-1 | 0.01 | B |
| Example 17 | InAs | 1.35 | 940 | 3.9 | 75 | L2-8 | 23 | S-1 | 0.01 | A |
| Example 18 | InAs | 1.35 | 940 | 3.9 | 75 | L1-1, | 23 | S-1 | 0.01 | B |
| | | | | | | L2-9 | | | | |
| Example 19 | InAs | 1.35 | 940 | 3.9 | 75 | L1-1 | 23 | S-1, | 0.01 | B |
| | | | | | | | | S-2 | | |
| Comparative | InAs | 1.35 | 940 | 3.9 | 75 | L2-8 | 23 | S-1 | 0.0001 | C |
| Example 1 | | | | | | | | | | |
| Comparative | InAs | 1.35 | 940 | 3.9 | 75 | L2-8 | 23 | S-1 | 0.5 | C |
| Example 2 | | | | | | | | | | |

TABLE 2

| | Quantum dots | | | | | | | | | |
|---|---|---|---|---|---|---|---|---|---|---|
| | | | | Average | | | | | | |
| | | | | primary | | | | | | |
| | | Band | | particle | | Ligand | | | Moisture | |
| | | gap | λmax | diameter | Content | | Content | Organic | content | |
| | Type | (eV) | (nm) | (nm) | (mass %) | Type | (mass %) | solvent | (mass %) | dispersibility |
| Example 101 | InAs | 0.86 | 1450 | 8.2 | 75 | L1-1 | 23 | S-1 | 0.01 | A |
| Example 102 | InPAs | 0.86 | 1450 | 7.6 | 75 | L1-1 | 23 | S-1 | 0.01 | A |
| Example 103 | InAs | 0.86 | 1450 | 8.2 | 75 | L2-1 | 23 | S-1 | 0.01 | A |
| Example 104 | InAs | 0.86 | 1450 | 8.2 | 75 | L2-2 | 23 | S-1 | 0.01 | A |
| Example 105 | InAs | 0.86 | 1450 | 8.2 | 75 | L1-1 | 23 | S-2 | 0.01 | B |
| Example 106 | InAs | 0.86 | 1450 | 8.2 | 75 | L1-1 | 23 | S-3 | 0.01 | B |
| Example 107 | InAs | 0.86 | 1450 | 8.2 | 75 | L2-3 | 23 | S-1 | 0.01 | B |
| Example 108 | InAs | 0.86 | 1450 | 8.2 | 75 | L2-4 | 23 | S-1 | 0.01 | A |
| Example 109 | InAs | 0.86 | 1450 | 8.2 | 75 | L2-5 | 23 | S-1 | 0.01 | A |
| Example 110 | InAs | 0.86 | 1450 | 8.2 | 75 | L2-6 | 23 | S-1 | 0.01 | B |
| Example 111 | InAs | 0.86 | 1450 | 8.2 | 75 | L2-7 | 23 | S-1 | 0.01 | B |
| Example 112 | InAs | 0.86 | 1450 | 8.2 | 75 | L1-2 | 23 | S-1 | 0.01 | A |
| Example 113 | InAs | 0.86 | 1450 | 8.2 | 75 | L1-3 | 23 | S-1 | 0.01 | A |
| Example 114 | InAsSb | 0.86 | 1450 | 6 | 75 | L1-1 | 23 | S-1 | 0.01 | A |
| Example 115 | InAs | 0.86 | 1450 | 8.2 | 75 | L2-8 | 23 | S-1 | 0.01 | A |
| Example 116 | InAs | 0.86 | 1450 | 8.2 | 75 | L1-1, | 23 | S-1 | 0.01 | B |
| | | | | | | l2-9 | | | | |
| Example 117 | InAs | 0.86 | 1450 | 8.2 | 75 | L1-1 | 23 | S-1, | 0.01 | B |
| Comparative | InAs | 0.86 | 1450 | 8.2 | 75 | L2-8 | 23 | S-1 | 0.0001 | C |
| Example 101 | | | | | | | | | | |
| Comparative | InAs | 0.86 | 1450 | 8.2 | 75 | L2-8 | 23 | S-1 | 0.5 | C |
| Example 102 | | | | | | | | | | |

The numerical values in the column of λmax in the above table are values of the maximal absorption wavelength of the quantum dots, and the numerical values in the column of the average primary particle diameter are values of the average primary particle diameter of the quantum dots. In addition, the numerical values described in the column of the content in the above table are values of the content of the quantum dots or the ligand in the components from which the organic solvent and the water are removed. In addition, the details of the materials described by abbreviations among the materials described in the column of the type in the above table are as follows.

In the dispersion liquids of Examples 1 to 19, 101 to 117, Comparative Examples 1, 2, 101, and 102, the content of the quantum dots in the components from which the ligand, the organic solvent, and the water were removed was 95% by mass or more, and the total content of the quantum dots and the ligand in the components from which the organic solvent and the water were removed was 95% by mass or more.

### (Ligand)

L1-1: InBr₃
L1-2: InCl₃
L1-3: InI₃
L2-1: 3-aminopropan-1-ol
L2-2: 3-mercaptopropionic acid
L2-3: trifluoroacetic acid
L2-4: 3-mercapto-2,2-bis(mercaptomethyl)-1-propanol
L2-5: 3-aminopropan-1-ol
L2-6: methylphosphonic acid
L2-7: methanesulfonic acid
L2-8: mercaptoethanol
L2-9: methylamine acetic acid

### (Organic Solvent)

S-1: N,N-dimethylformamide
S-2: dimethyl sulfoxide
S-3: ethylene glycol

As shown in the above table, all the dispersion liquids of the Examples had excellent dispersibility.

### <Production of Zinc Oxide Particle Dispersion Liquid>

### (Zinc Oxide Particle Dispersion Liquid 1)

1.5 mmol of zinc acetate dihydrate and 15 mL of dimethyl sulfoxide (DMSO) were weighed in a flask and stirred to obtain a zinc acetate solution.

A TMACl solution in which 4 mmol of tetramethylammonium chloride (TMACl) was dissolved in 4 ml of methanol and a KOH solution in which 4 mmol of potassium hydroxide (KOH) was dissolved in 4 ml of methanol were prepared. The KOH solution was slowly added to the TMACl solution while vigorously stirring, and after stirring for 30 minutes, insoluble components were removed through a filter having a pore diameter of 0.45 μm to obtain a tetramethylammonium hydroxide (TMAH) solution.

6 ml of the TMAH solution was added to the zinc acetate solution in the flask at a dropping rate of 6 ml/min. After holding for 1 hour, the reaction solution was recovered. An excessive amount of acetone was added to the reaction solution, and the mixture was centrifuged at 10,000 rpm for 10 minutes, the supernatant was removed, the precipitate was dispersed in methanol, and then the precipitate was precipitated again with acetone. Then, 5 ml of ethanol and 80 μl of aminoethanol were added thereto, and the mixture was subjected to ultrasonic dispersion to obtain a zinc oxide particle dispersion liquid 1 having a concentration of non-doped zinc oxide particles of about 30 mg/mL.

### <Production of Photodetector Element>

An indium tin oxide (ITO) film having a thickness of about 100 nm was formed on a quartz glass by a sputtering method to form a first electrode.

Next, a solution obtained by dissolving 1 g of zinc acetate dihydrate and 284 μl of ethanolamine in 10 ml of 2-methoxyethanol was spin-coated on the ITO film (first electrode) at 3,000 rpm. Thereafter, the mixture was heated at 200 °C for 30 minutes to form a sol-gel film of zinc oxide having a thickness of about 40 nm. Next, the zinc oxide particle dispersion liquid 1 was added dropwise onto the sol-gel film, spin-coated at 2,500 rpm, and heated at 70 °C for 30 minutes, and this step was performed twice. Thereafter, using UVO-CLEANER MODEL 144AX-100 manufactured by Jelight Company Inc., an ultraviolet ozone treatment was performed for 5 minutes under conditions of 30 mW/cm² (wavelength peak: 254 nm), and a particle film of zinc oxide having a thickness of about 130 nm was formed to form an electron transport layer.

Next, the dispersion liquid shown in the following table was added dropwise onto the electron transport layer, and then spin-coated at 1,000 rpm and dried at 120 °C for 10 minutes to form a quantum dot film. The step of forming the quantum dot film was repeated four times to form a photoelectric conversion film having a thickness of 180 nm. Next, the photoelectric conversion film was dried in a glove box for 10 hours. Each dispersion liquid was used immediately after production and after being stored at 25 °C for 1 month in a nitrogen atmosphere.

Next, a dichlorobenzene solution (concentration: 5 mg/mL) of PTB7 (poly({4,8-bis[(2-ethylhexyl)oxy]benzo[1,2-b:4,5-b′]dithiophene-2,6-diyl}{3-fluoro-2-[(2-ethylhexyl)carbonyl]thieno[3,4-b]thiophenediyl})) was spin-coated on the photoelectric conversion film at 2,000 rpm, and then dried in a glove box for 10 hours to form a hole transport layer.

Next, a MoO₃ film having a thickness of 5 nm was formed on the hole transport layer by a vacuum evaporation method through a metal mask, and then an Au film (second electrode) having a thickness of 100 nm was formed to manufacture a photodiode-type photodetector element.

### <Evaluation>

### (Photodetector Elements Using Dispersion Liquids of Examples 1 to 19 (Production Examples 1 to 19) and Photodetector Elements Using Dispersion Liquids of Comparative Examples 1 and 2 (Production Examples R1 and R2))

For each photodetector element, the external quantum efficiency was evaluated using a semiconductor parameter analyzer (C4156, manufactured by Agilent Technologies, Inc.).

First, the current-voltage characteristics (I-V characteristics) were measured while sweeping the voltage from 0 V to −2 V in a state where light was not applied, and the dark current value was evaluated. Here, the dark current value was defined as a value at −1 V. Subsequently, the I-V characteristics were measured while sweeping the voltage from 0 V to −2 V in a state where monochromatic light having a wavelength of 940 nm was applied. A value obtained by subtracting the dark current value from the current value in a state where −1 V was applied was defined as a photocurrent value, and the external quantum efficiency was calculated from the value.

In the column of the initial performance in the following table, the value of the external quantum efficiency using the photodetector element manufactured using the dispersion liquid immediately after the production in each production example is described.

In addition, for the photodetector element of each production example, the degree of fluctuation in the external quantum efficiency was calculated from the following formula, and the temporal stability was evaluated based on the following criteria.

Degree of fluctuation in external quantum efficiency=|1−(external quantum efficiency of photodetector element manufactured using dispersion liquid after storage at 25 °C for 1 month/external quantum efficiency of photodetector element manufactured using dispersion liquid immediately after manufacture)|×100
A: The degree of fluctuation in the external quantum efficiency is less than 1%.
B: The degree of fluctuation in the external quantum efficiency is 1% or more and less than 5%.
C: The degree of fluctuation in the external quantum efficiency is 5% or more and less than 10%.
D: The degree of fluctuation in the external quantum efficiency is 10% or more.

TABLE 3

External quantum
efficiency

| | Used | Initial | |
|---|---|---|---|
| | dispersion | performance | Temporal |
| | liquid | (%) | stability |
| Production | Example 1 | 40 | A |
| Example 1 | | | |
| Production | Example 2 | 39 | A |
| Example 2 | | | |
| Production | Example 3 | 35 | A |
| Example 3 | | | |
| Production | Example 4 | 35 | B |
| Example 4 | | | |
| Production | Example 5 | 34 | A |
| Example 5 | | | |
| Production | Example 6 | 34 | A |
| Example 6 | | | |
| Production | Example 7 | 38 | A |
| Example 7 | | | |
| Production | Example 8 | 38 | A |
| Example 8 | | | |
| Production | Example 9 | 35 | A |
| Example 9 | | | |
| Production | Example 10 | 34 | B |
| Example 10 | | | |
| Production | Example 11 | 35 | B |
| Example 11 | | | |
| Production | Example 12 | 35 | A |
| Example 12 | | | |
| Production | Example 13 | 34 | A |
| Example 13 | | | |
| Production | Example 14 | 38 | B |
| Example 14 | | | |
| Production | Example 15 | 38 | B |
| Example 15 | | | |
| Production | Example 16 | 39 | B |
| Example 16 | | | |
| Production | Example 17 | 37 | B |
| Example 17 | | | |
| Production | Example 18 | 35 | B |
| Example 18 | | | |
| Production | Example 19 | 37 | B |
| Example 19 | | | |
| Production | Comparative | 30 | D |
| Example R1 | Example 1 | | |
| Production | Comparative | 25 | D |
| Example R2 | Example 2 | | |

As shown in the above table, the photodetector element manufactured using the dispersion liquid of Examples had a higher external quantum efficiency and was excellent in the evaluation of the temporal stability, as compared with the photodetector element manufactured using the dispersion liquid of Comparative Examples.

### (Photodetector Elements Using Dispersion Liquids of Examples 101 to 117 (Production Examples 101 to 117) and Photodetector Elements Using Dispersion Liquids of Comparative Examples 101 and 102 (Production Examples R101 and R102))

For each photodetector element, the external quantum efficiency was evaluated using a semiconductor parameter analyzer (C4156, manufactured by Agilent Technologies, Inc.).

First, the current-voltage characteristics (I-V characteristics) were measured while sweeping the voltage from 0 V to −2 V in a state where light was not applied, and the dark current value was evaluated. Here, the dark current value was defined as a value at −1 V. Subsequently, the I-V characteristics were measured while sweeping the voltage from 0 V to −2 V in a state where monochromatic light having a wavelength of 1,450 nm was applied. A value obtained by subtracting the dark current value from the current value in a state where −1 V was applied was defined as a photocurrent value, and the external quantum efficiency was calculated from the value.

In the column of the initial performance in the following table, the value of the external quantum efficiency using the photodetector element manufactured using the dispersion liquid immediately after the manufacture in each production example is described.

In addition, for the photodetector element of each production example, the degree of fluctuation in the external quantum efficiency was calculated from the following formula, and the temporal stability was evaluated based on the following criteria.

Degree of fluctuation in external quantum efficiency=|1−(external quantum efficiency of photodetector element manufactured using dispersion liquid after storage at 25 °C for 1 month/external quantum efficiency of photodetector element manufactured using dispersion liquid immediately after manufacture)|×100
A: The degree of fluctuation in the external quantum efficiency is less than 1%.
B: The degree of fluctuation in the external quantum efficiency is 1% or more and less than 5%.
C: The degree of fluctuation in the external quantum efficiency is 5% or more and less than 10%.
D: The degree of fluctuation in the external quantum efficiency is 10% or more.

TABLE 4

External quantum
efficiency

| | Used | Initial | |
|---|---|---|---|
| | dispersion | performance | Temporal |
| | liquid | (%) | stability |
| Production | Example 101 | 10 | A |
| Example 101 | | | |
| Production | Example 102 | 7 | A |
| Example 102 | | | |
| Production | Example 103 | 7 | A |
| Example 103 | | | |
| Production | Example 104 | 7 | A |
| Example 104 | | | |
| Production | Example 105 | 9 | A |
| Example 105 | | | |
| Production | Example 106 | 9 | A |
| Example 106 | | | |
| Production | Example 107 | 8 | A |
| Example 107 | | | |
| Production | Example 108 | 7 | B |
| Example 108 | | | |
| Production | Example 109 | 7 | B |
| Example 109 | | | |
| Production | Example 110 | 8 | A |
| Example 110 | | | |
| Production | Example 111 | 6 | A |
| Example 111 | | | |
| Production | Example 112 | 9 | B |
| Example 112 | | | |
| Production | Example 113 | 9 | B |
| Example 113 | | | |
| Production | Example 114 | 7 | A |
| Example 114 | | | |
| Production | Example 115 | 7 | B |
| Example 115 | | | |
| Production | Example 116 | 7 | B |
| Example 116 | | | |
| Production | Example 117 | 7 | B |
| Example 117 | | | |
| Production | Comparative | 5 | D |
| Example R101 | Example 101 | | |
| Production | Comparative | 3 | D |
| Example R102 | Example 102 | | |

As shown in the above table, the photodetector element manufactured using the dispersion liquid of Examples had a higher external quantum efficiency and was excellent in the evaluation of the temporal stability, as compared with the photodetector element manufactured using the dispersion liquid of Comparative Examples.

By using the photodetector element obtained in Examples and producing an image sensor by a known method together with an optical filter produced according to the methods described in WO2016/186050A and WO2016/190162A, an image sensor having good visible-light and infrared imaging performance can be obtained.

### EXPLANATION OF REFERENCES

1: photodetector element
11: first electrode
12: second electrode
13: photoelectric conversion film
21: electron transport layer
22: hole transport layer

What is claimed is:

1. A dispersion liquid comprising:
quantum dots having a band gap of 1.35 eV or less;
a ligand;
an organic solvent; and
water,
wherein a content of the quantum dots in components obtained by excluding the ligand, the organic solvent, and the water from the dispersion liquid is 50% by mass or more, and
a content of the water in the dispersion liquid is 0.001% to 0.3% by mass.

2. The dispersion liquid according to claim 1, wherein the content of the water in the dispersion liquid is 0.01% to 0.1% by mass.

3. The dispersion liquid according to claim 1, wherein the quantum dots are group II-V quantum dots.

4. The dispersion liquid according to claim 1, wherein an average primary particle diameter of the quantum dots is 0.5 nm or more and less than 100 nm.

5. The dispersion liquid according to claim 1, wherein the quantum dots include at least one selected from InAs, InSb, InPAs, or InAsSb.

6. The dispersion liquid according to claim 1, wherein the quantum dots have a maximum absorption in a wavelength range of 900 to 1,700 nm.

7. The dispersion liquid according to claim 1, wherein the ligand includes an inorganic halide.

8. The dispersion liquid according to claim 1, wherein the ligand includes an organic ligand having at least one functional group selected from a carboxy group, a mercapto group, an amino group, a hydroxy group, a phospho group, a phosphonic acid group, or a sulfo group.

9. The dispersion liquid according to claim 1, wherein the organic solvent is a polar solvent.

10. A method for producing a photoelectric conversion film, comprising:
applying the dispersion liquid according to claim 1 onto a support to form a composition layer; and
drying the composition layer.

11. A method for producing a photodetector element, comprising the method for producing a photoelectric conversion film according to claim 10.

12. A method for producing an image sensor, comprising the method for producing a photoelectric conversion film according to claim 10.
